(19) United States
(12) Patent Application Publication
(10) Pub. No.: US 2008/0012065 A1
(43) Pub. Date: Jan. 17, 2008

(54) Bandgap engineered charge storage layer for 3D TFT

(75) Inventor: Tanmay Kumar, Pleasanton, CA (US)

Correspondence Address: FOLEY AND LARDNER LLP;SUITE 500, 3000 K STREET NW, WASHINGTON, DC, 20007, US

(73) Assignee: SanDisk Corporation

(21) Appl. No.: 11/483,671

(22) Filed: Jul. 11, 2006

(51) Int. Cl. H01L 29/792

(52) U.S. Cl. 257/324

(57) ABSTRACT

One SONOS-type device contains (a) a charge storage dielectric that includes a band engineered layer that has a wider bandgap facing one of a blocking dielectric and a tunneling dielectric than facing the other one of the blocking dielectric and the tunneling dielectric, and (b) a semiconductor channel region that contains polysilicon. Another SONOS-type device contains a charge storage dielectric that includes a band engineered layer that has a wider bandgap facing one of a blocking dielectric and a tunneling dielectric than facing the other one of the blocking dielectric and the tunneling dielectric. The device is located in a monolithic three dimensional memory array. Yet another SONOS-type device contains a charge storage dielectric that includes a band engineered layer that has a wider bandgap facing one of a blocking dielectric and a tunneling dielectric than facing the other one of the blocking dielectric and the tunneling dielectric and also includes at least one of: (a) a first dielectric layer located between the tunneling dielectric and the band engineered layer, and (b) a second dielectric layer located between the blocking dielectric and the band engineered layer.

### BACKGROUND OF THE INVENTION

One conventional type of nonvolatile memory cell is a SONOS device, which operates by trapping charge in a charge storage layer. The presence or absence of stored charge distinguishes a programmed cell from an unprogrammed cell. Thus the ability of the cell to retain stored charge is crucial to its performance as a memory device. Stored charge tends to be lost from the cell over time and with successive write-erase cycles.

Attempts have been made to improve retention of charge by optimizing the characteristics of the charge storage layer such as using silicon oxynitride instead of silicon nitride, which is the most frequently used material for the charge storage layer, applying heat treatments to silicon nitride, using multiple charge storage layers, etc. Some of these methods have shown certain benefit, but a need still exists to further improve retention and endurance of SONOS-type devices.

### SUMMARY OF THE INVENTION

One embodiment of the invention provides a SONOS-type device, comprising (A) a semiconductor channel region located between a source region and a drain region, (B) a tunneling dielectric in contact with the semiconductor channel region, (C) a charge storage dielectric in contact with the tunneling dielectric, (D) a blocking dielectric in contact with the charge storage dielectric, and (E) a gate electrode in contact with the blocking dielectric, wherein the charge storage dielectric comprises a band engineered layer that has a wider bandgap facing one of the blocking dielectric and the tunneling dielectric than facing the other one of the blocking dielectric and the tunneling dielectric, and the semiconductor channel region comprises polysilicon.

Another embodiment of the invention provides a SONOS-type device, comprising (A) a semiconductor channel region located between a source region and a drain region, (B) a tunneling dielectric in contact with the semiconductor channel region, (C) a charge storage dielectric in contact with the tunneling dielectric, (D) a blocking dielectric in contact with the charge storage dielectric, and (E) a gate electrode in contact with the blocking dielectric, wherein the charge storage dielectric comprises a band engineered layer that has a wider bandgap facing one of the blocking dielectric and the tunneling dielectric than facing the other one of the blocking dielectric and the tunneling dielectric, and the device comprises a portion of a monolithic three dimensional memory array.

Yet another embodiment of the invention provides a SONOS-type device, comprising (A) a semiconductor channel region located between a source region and a drain region, (B) a tunneling dielectric in contact with the semiconductor channel region, (C) a charge storage dielectric in contact with the tunneling dielectric, (D) a blocking dielectric in contact with the charge storage dielectric, and (E) a gate electrode in contact with the blocking dielectric. The charge storage dielectric comprises (i) a band engineered layer that has a wider bandgap facing one of the blocking dielectric and the tunneling dielectric than facing the other one of the blocking dielectric and the tunneling dielectric, and (ii) at least one of (a) a first dielectric layer located between the tunneling dielectric and the band engineered layer, said first dielectric layer comprises a material different from that of the band engineered layer and different from that of the tunneling dielectric, and (b) a second dielectric layer located between the blocking dielectric and the band engineered layer, said second dielectric layer comprises a material different from that of the band engineered layer and different from that of the blocking dielectric.

### BRIEF DESCRIPTION OF THE DRAWINGS

FIGS. 1a, 1b, and 1c are side cross-sectional views showing structure and operation of a traditional SONOS cell.

FIG. 2 is an energy band diagram of the SONOS cell of FIGS. 1a, 1b, and 1c.

FIG. 3 is an energy band diagram of a SONOS device with a bandgap engineered nitride.

FIG. 4 is an energy band diagram of a SONOS device having a charge storage dielectric that includes bandgap engineered nitride layer and optional dielectric layers.

### DETAILED DESCRIPTION OF THE PREFERRED EMBODIMENTS

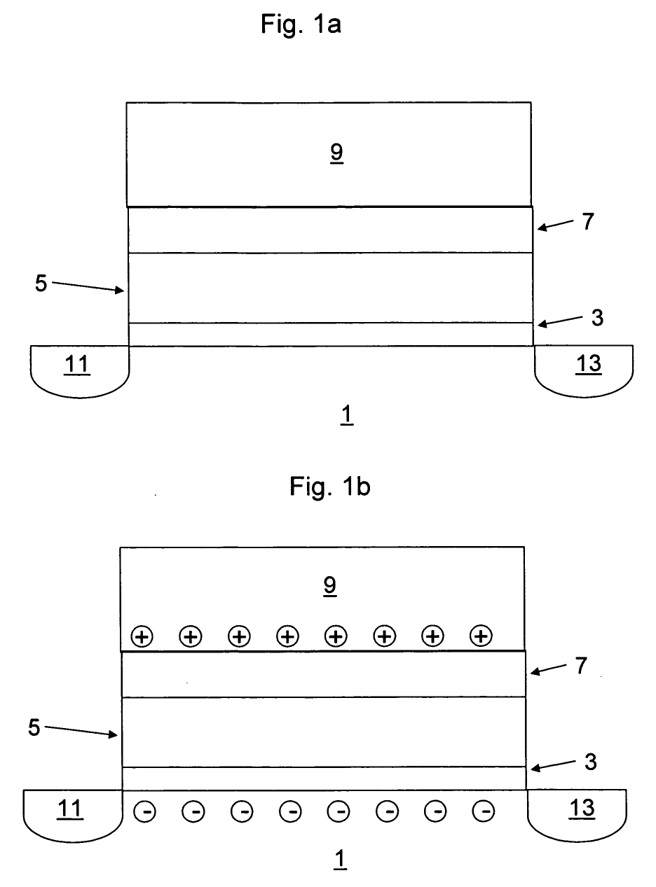

The embodiments of the present invention provide a nonvolatile charge-storage memory device related to a traditional SONOS device. A prior art SONOS device, as shown in FIG. 1a, is a field effect transistor that operates as a nonvolatile memory cell by storing charge. A typical SONOS device is formed on a substrate 1 (conventionally a monocrystalline silicon wafer), upon which is formed a tunneling oxide 3 (normally silicon dioxide), a charge storage layer 5 (normally silicon nitride), a blocking oxide 7 (normally silicon dioxide), and a gate electrode 9 (typically metal or highly doped polycrystalline silicon, herein called polysilicon.) The Silicon-Oxide-Nitride-Oxide-Silicon stack of substrate 1, tunneling oxide 3, charge storage layer 5, blocking oxide 7, and gate electrode 9 gives the SONOS device its name. Source region 11 and drain region 13 are formed in the substrate, for example by ion implantation.

Turning to FIG. 1b, in normal operation of, for example, a n-type metal-oxide-semiconductor (NMOS) device, a positive charge is applied to the gate electrode 9. The excess of positive charge in the gate electrode 9 (positive charge carriers indicated by a “+” in a circle) attracts electrons (indicated by a “−” in a circle) in silicon substrate 1. When enough charge is applied, the threshold voltage V_{T} is reached, and a conductive channel region forms in the substrate 1; at this point the transistor is considered to be “on,” or conducting between source and drain.

With sufficient positive charge applied to the gate electrode 9, some electrons from substrate 1, attracted to the positive charge on the gate electrode 9, will tunnel through the very thin tunneling oxide 3, and will be trapped in the charge storage layer 5, as shown in FIG. 1c. When the positive charge is no longer applied to the gate electrode 9, these electrons remain trapped in the charge storage layer 5. In SONOS devices, silicon nitride (Si₃N₄) is typically used for the charge storage layer 5, because it tends to have “traps,” or flaws in the crystal lattice, which can act as low-energy sites, attracting free electrons and tending to hold them in place. The presence or absence of trapped charge in the charge storage layer 5 can be sensed, and distinguishes a programmed cell from an unprogrammed cell.

For simplicity, this example described the operation and structure of an NMOS device, in which the source and drain are heavily doped n-type silicon and the substrate is lightly doped p-type. Those skilled in the art will appreciate that a p-type metal-oxide-semiconductor (PMOS) device example could have been given instead.

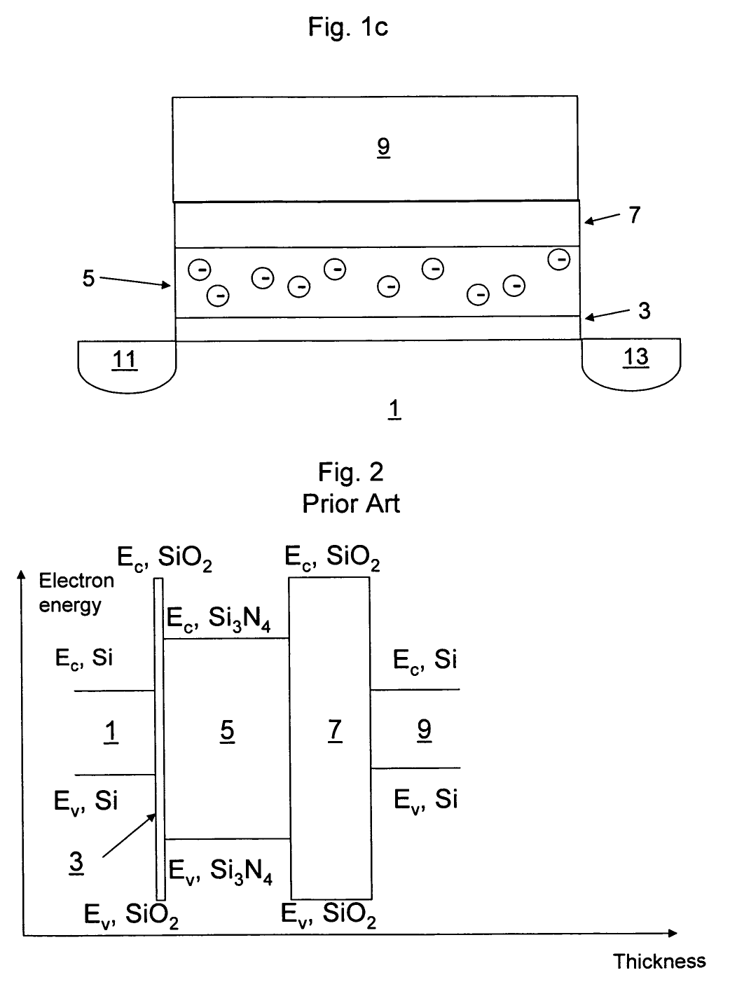

The energy required for a charge carrier to move from one layer to the next is illustrated in FIG. 2, which is an energy band diagram of the SONOS device of FIGS. 1a, 1b, and 1c. Device thickness increases on the X-axis, and electron energy increases (and hole energy decreases) on the Y-axis. FIG. 2 depicts the energy gap between the valence band edge (E_{V}) and the conduction band edge (E_{C}) for each material. The gap between E_{V}, Si and E_{C}, Si for silicon substrate 1 is 1.1 eV. The gap between E_{V}, SiO₂ and E_{C}, SiO₂, for the silicon dioxide tunneling layer 3 is about 8 eV. The gap between E_{V}, Si₃N₄ and E_{C}, Si₃N₄ in the silicon nitride charge storage layer 5 is about 5.1 eV. The E_{V}, SiO₂-E_{C}, SiO₂ gap for the silicon dioxide blocking layer 7 is about 8 eV. The E_{V}, Si-E_{C}, Si gap for the polysilicon gate electrode 9 is 1.1 eV. The large energy difference between E_{C}, Si of substrate 1 and E_{C}, SiO₂ of the tunneling layer 3 (this gap is 3.1 eV) makes the tunneling oxide 3 an effective barrier to electron flow. When charge is applied, these barriers are artificially lowered and electrons are able to move. For example, with no charge applied, an electron in substrate 1 is prevented from reaching the charge storage layer 5 by the tunneling oxide 3. With charge applied, the barrier is effectively lowered, allowing electron flow to the charge storage layer 5. With charge removed, the barrier is back in place, and the electron is trapped in the charge storage layer 5 by the gap between E_{C}, Si₃N₄ of the charge storage layer 5 and E_{C}, SiO₂ of the tunneling oxide 3 or the blocking oxide 7 (this gap is 1.05 eV).

For simplicity, the preceding description speaks of electron flow. It will be understood that holes flow as well, and the more general term “charge carrier” can be used instead, and that different charge polarities can be used.

However, retention, i.e. the ability to retain stored charge, in the charge storage layer of a SONOS memory cell is imperfect. To minimize the voltages required to operate the device, the tunneling oxide 3, the charge storage layer 5, and the blocking oxide 7 are formed as thin as possible. When charge carriers trapped in the charge storage layer 5 are exposed to any voltage, for example during reading of the cell, or when nearby cells are programmed or erased, the charge carriers will migrate within the charge storage layer 5. If charge carriers migrate close to either the tunneling oxide 3 or the blocking oxide 7, some danger exists that over time they will escape. Tunneling oxide 3 is typically a high quality oxide, but is very thin, while the blocking oxide 7, although thicker, is normally a lower quality oxide and will have flaws.

For the purpose of this discussion, “SONOS-type device” will mean a field effect transistor comprising 1) a semiconductor channel region located between a source region and a drain region, 2) a tunneling dielectric in contact with the channel region, 3) a charge storage layer comprising only dielectric material in contact with the tunneling dielectric, 4) a blocking dielectric in contact with the charge storage layer, and 5) a gate electrode in contact with the blocking dielectric. Although the channel region is called a channel region because it acts as a conductive channel when the transistor is on, as used herein the channel region will be called a channel region, whether the transistor is on or off.

A traditional SONOS device is of course a SONOS-type device, but the term as used herein is intended to be broader. In a SONOS-type device, the gate electrode need not be silicon; it can be either semiconductor or metal, for example, it may comprise tungsten. Similarly, any appropriate material can be used for the channel region. A SONOS-type device has layers having the same functions as the silicon channel region, tunneling oxide, nitride charge storage layer, blocking oxide, and silicon gate electrode of a traditional SONOS device, but one or more materials can be substituted for the material traditionally used for any of these layers. The device can be formed on a monocrystalline semiconductor substrate, or on a polysilicon substrate, as a part of thin film transistor (TFT) array. The gate electrode can be formed above the channel region or vice versa; i.e. the device can be “right side-up” or “upside-down.” Examples of rightside-up and upside-down SONOS cells are found in co-pending U.S. Published Application No. US 2003-0155582, published Aug. 21, 2003, by Maitreyee Mahajani et. al., entitled “Gate Dielectric Structures for Integrated Circuits and Methods for Making and Using Such Gate Dielectric Structures,” hereby incorporated by reference. A SONOS-type device can operate either in enhancement mode or in depletion mode.

In various aspects of the present invention, the charge storage layer includes a band engineered layer, i.e. a layer of a dielectric that has a wider bandgap on the side facing one of the blocking dielectric and the tunneling dielectric than on the side facing the other one of the blocking dielectric and the tunneling dielectric. For an n-type SONOS-type (i.e., an NMOS type) device, the band engineered dielectric has a wider bandgap facing the blocking dielectric than facing the tunneling dielectric. For a p-type SONOS-type (i.e., a PMOS type) device, the band engineered dielectric has a wider bandgap facing the tunneling dielectric than the blocking dielectric. Although, for simplicity, the following disclosure discusses mainly the band engineered layer in the n-type SONOS-type device, those skilled in the art will be able to apply this discussion for the band engineered layer in the p-type device as well taking into account the above consideration.

The band engineered layer has a variable composition. For example, referring to FIG. 1a, the upper side of layer 5 will have a composition that has a wider bandgap, than a composition of the lower side of layer 5. For an upside-down transistor, the lower side will have a wider bandgap than the upper side. In some embodiments, the band gap can increase gradually or continuously from one side of the band engineered dielectric to the opposite side. The dielectric of the band engineered layer can be, for example, silicon nitride or silicon oxynitride. For silicon nitride, the bandgap can be tuned by changing a ratio between Si and N throughout the layer's thickness. The higher Si/N ratio corresponds to a narrower band gap composition, which faces the tunneling dielectric, while the lower Si/N ratio corresponds to a wider band gap composition, which faces the blocking dielectric.

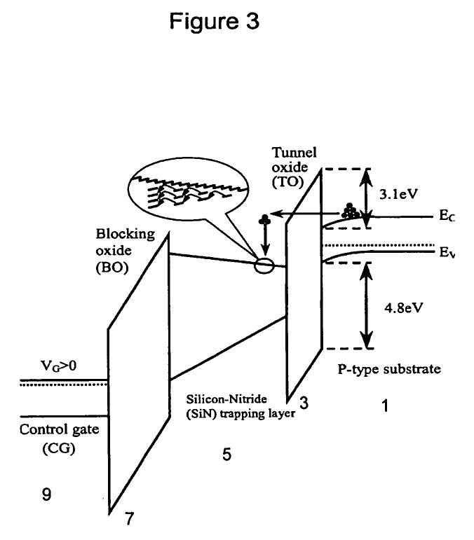

FIG. 3 illustrates a band diagram of a SONOS-type device that has a charge storage dielectric that includes a band engineered layer of silicon nitride. The side of the band engineered layer facing the blocking oxide is nitrogen-rich silicon nitride, while the side facing the tunneling oxide is silicon-rich silicon nitride.

One non-limiting purpose of the bandgap increasing from the tunneling dielectric side to the blocking dielectric side is to create more accessible trapping levels for the electrons injected from the tunneling oxide. As shown in the inset of FIG. 3, the electrons that fall in shallow trapping levels can be transferred to adjacent deeper levels easily by lateral hopping. In addition, the increased barrier height between silicon nitride and tunneling oxide that can reduce the back-tunneling probability also can help in promoting the charge-trapping efficiency of the nitride layer. For standard, i.e. stoichiometric, silicon nitride, most deep trapping levels are buried underneath and may not be able to capture electrons as simply as shallow levels. On the other hand, the trapping levels of uniform, i.e. non-engineered bandgap, silicon-rich silicon nitride are simply too shallow to grasp electrons firmly and, hence, lead to high detrapping rate and lower trapping efficiency. The availability and accessibility of trapping levels in the band engineered layer can increase the charge retention and endurance of the SONOS-type device.

In some embodiments, the SONOS-type device that includes a band engineered charge storage layer has the semiconductor channel region that comprises polysilicon. When the SONOS-type device comprises a thin-film transistor (TFT) device, the semiconductor channel region can comprise a polysilicon layer. In a TFT, the polysilicon channel layer can be formed over an insulating substrate or over an insulating layer located over a semiconductor or a conductive substrate.

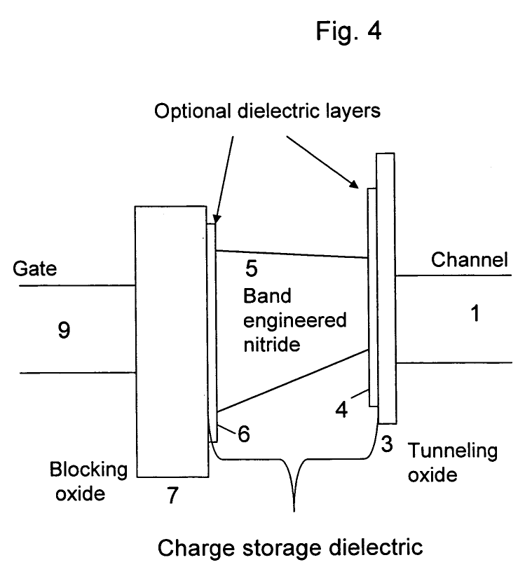

In some embodiments, the charge storage dielectric of the SONOS-type device can further include one or more dielectric layers located between the band engineered layer and the tunneling dielectric, and/or between the band engineered layer and the blocking dielectric. Such dielectric layer, when located between the band engineered layer and the tunneling dielectric, comprises a material different from that of the tunneling dielectric and different from that of the band engineered layer. Similarly, when such dielectric layer is located between the band engineered layer and the blocking dielectric, the material of the dielectric layer is different from that of the blocking dielectric and that of the band engineered layer. FIG. 4 presents an example of the device having one such optional dielectric layer 4 located between the band engineered layer 5 and the tunneling dielectric 3 and another optional dielectric layer 6 located between the band engineered layer 5 and the blocking dielectric 7.

Dielectric materials that can be used for in such dielectric layers 4, 6 can be oxides such as hafnium oxide, zirconium oxide, tantalum pentoxide, yttrium oxide, calcium oxide, magnesium oxide, etc., or, alternatively, oxynitrides, such silicon oxynitride. These dielectric materials may be stoichiometric or nonstoichiometric. Any appropriate dielectric material can be used, however, preferred materials have a dielectric constant greater than or equal to 3.9; more preferred materials have a dielectric constant greater than or equal to about 7. In some devices, it may be preferred to use materials having a dielectric constant greater than about 25.

Layers 4, 6 can be the same or different from each other in thickness and material. Referring to FIG. 4, layer 4 comprises a material different from the SiO₂ of layer 3 and different from the silicon nitride of layer 5, while layer 6 comprises a material different from the SiO₂ of layer 7 and different from the silicon nitride of layer 5.

The charge storage dielectric that comprises more than one layer can improve not only retention but also endurance of a SONOS-type device. Endurance is the ability of a rewritable memory cell to retain the distinction between its programmed and unprogrammed state, and is generally expressed in numbers of write-erase cycles. It is typical for design specifications for rewritable memories to require them to be able to survive about one million write-erase cycles and still be readable.

It is believed that one reason for a memory cell to become unreadable over time may be that cumulative damage to the silicon nitride of the charge storage layer may cause charge carriers to become too mobile within the layer, allowing them to escape. A SONOS-type device that has a charge storage dielectric comprising more than one dielectric layer may have improved endurance, because decreased migration of charge carriers causes less damage to the charge storage dielectric.

In some embodiments, the SONOS device that includes the band engineered layer may comprise a portion of monolithic three dimensional array.

Monolithic three dimensional memory arrays having rewritable memory cells are described in Lee et. al., U.S. Pat. No. 6,881,994, “Monolithic Three Dimensional Array Of Charge Storage Devices Containing A Planarized Surface” issued Apr. 19, 2005, Walker et. al., U.S. Pat. No. 7,005,350, “Method for Fabricating Programmable Memory Array Structures Incorporating. Series-Connected Transistor Strings,” issued Feb. 26, 2006; and Scheuerlein et. al., U.S. patent application “Programmable Memory Array Structure Incorporating Series-Connected Transistor Strings and Methods for Fabrication and Operation of Same,” published as US 2004-0125629 Jul. 1, 2004, all assigned to the assignee of the present invention and hereby incorporated by reference.

A monolithic three dimensional memory array is one in which multiple memory levels are formed above a single substrate, such as a wafer, with no intervening substrates. The term “monolithic” means that layers of each level of the array are directly deposited on the layers of each underlying level of the array. In contrast, two dimensional arrays may be formed separately and then packaged together to form a non-monolithic memory device. For example, non-monolithic stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

The fabrication of a SONOS-type device with a band engineered layer can be performed as follows. The fabrication can start with a substrate, such as a monocrystalline silicon wafer. Alternatively, a layer of polysilicon can be formed over an insulating substrate or over an insulating layer over a semiconductor or conducting substrate for a formation of a thin film transistor (TFT) device. The polysilicon layer may also be formed over a lower device level in a monolithic three dimensional array. The polysilicon layer may be initially deposited as polysilicon or as an amorphous silicon layer which is subsequently crystallized into a polysilicon layer. Source 11 and drain 13 regions are eventually formed in the wafer or polysilicon layer to delineate the channel region 1 in the wafer or polysilicon layer. For example, the source and drain region may be implanted into the wafer or the polysilicon layer using the subsequently formed gate electrode 9

A tunneling dielectric 3 can be then formed on channel 1 in the silicon substrate. Tunneling dielectric may be, for example, a 15 to 30 angstroms SiO₂ layer, which can be grown or deposited using any conventional technique. Any of several techniques may be used, such as a Rapid Thermal Oxidation (RTO) in a pure oxygen environment, or in an oxygen environment diluted with nitrogen. Thermal oxidation in a furnace may also be employed to form the tunneling dielectric.

Tunneling dielectric 3 can be also formed by an in situ steam generation (ISSG) process, as described in U.S. Published Application No. US 2003-0155582. For example, a monocrystalline silicon substrate or polysilicon layer can be exposed to such a process. The in situ steam generation process may be performed with the temperature between about 750 to about 1050 degrees Celsius and preferably at about 950 degrees Celsius. A suitable gas mixture is then introduced into the CVD apparatus and flowed over the semiconductor surface. A suitable gas mixture is any mixture containing oxygen and hydrogen, preferably introduced separately into the CVD chamber. Other inert or non-reactive gases (such as argon or helium) can be included in the gas mixture, but need not be present.

The flow rate of the oxygen and hydrogen in the ISSG process is optimized to obtain the desired growth of the oxide layer. In one embodiment, the oxygen flow rate can range from about 1 to about 5 liters/minute, preferably about 2 4 liters/minute, and more preferably about 3 liters/minute. The hydrogen flow rate can range from about 20 to about 1000 sccm (standard cubic centimeters/minute), preferably about 20 to about 100 sccm, and more preferably about 50 sccm.

This oxidation process is continued for a time sufficient to form a high-quality oxide layer with the desired thickness. In a preferred embodiment, the thickness of the oxide layer formed by the ISSG process can range from about 10 to about 200 angstroms, preferably about 10 to about 50 angstroms, and more preferably about 25 angstroms. As the deposition rate of the ISSG process described above can range from about 0.5 to about 2 angstroms/second, the time for the oxidation can range from about 10 seconds to about 60 seconds.

If desired, this oxidation process can be followed by an annealing process. Any suitable annealing process known in the art that maintains the quality of the oxide layer can be employed. In one embodiment, the annealing process is performed in a nitrogen and oxygen atmosphere, such as nitric oxide (NO), to form an oxynitride and improve the quality and reliability of the oxide layer.

If the SONOS-type device comprises the first optional dielectric layer 4 located between the tunneling dielectric 3 and the band engineered layer 5, then such first dielectric layer 4 can be deposited next. Any conventional method can be used to form this dielectric layer. The first dielectric layer can be, for example, between about 10 and about 50 angstroms thick; more preferably about 30 angstroms thick. Any process can be used, but this layer is preferably produced using a low-pressure CVD (LPCVD) process between about 100 mTorr and about 700 mTorr.

The band engineered layer 5 can be deposited directly on and in contact with the tunneling dielectric 3. Alternatively, the band engineered layer can be formed on and in contact on the first dielectric film 4. The band engineered layer can be, for example, a band engineered silicon nitride layer or a band engineered silicon oxynitride layer. The band engineered layer can be between from about 20 to about 100 angstroms thick, preferably about 50 angstroms thick.

The band engineered silicon nitride layer can be deposited by a low-pressure chemical vapor deposition (LPCVD) at a temperature between about 700° C. and 850° C., preferably at about 780° C., by tuning a gas flow rate ratio of dichlorosilane (SiH₂Cl₂) and ammonia (NH₃) source gases. Similarly, the band engineered silicon oxynitride layer can be deposited by tuning a gas flow rate ratio of dichlorosilane, ammonia and nitrous oxide (N₂O) source gases.

The SiH₂Cl₂/NH₃ gas flow rate ratio for stoichiometric silicon nitride, i.e. Si₃N₄, and uniform bandgap Si-rich silicon nitride can be about 0.23 and 2.07 respectively. The SiH₂Cl₂/NH₃ ratio in the beginning of the deposition process defines the Si/N ratio of silicon nitride facing the tunneling dielectric, while the SiH₂Cl₂/NH₃ ratio in the end of the deposition defines the Si/N ratio of silicon nitride facing the blocking dielectric. For example, if silicon nitride facing the tunneling dielectric is silicon rich, then the SiH₂Cl₂/NH₃ ratio in the beginning of the deposition can be about 2.07. If silicon nitride facing the blocking dielectric is stoichiometric, then the ratio is then decreased to about 0.23. If silicon nitride facing the blocking dielectric is nitrogen rich, then the ratio is decrease to about 0.1. To achieve a continuous change of the bandgap in the bandgap engineered layer 5, the SiH₂Cl₂/NH₃ ratio is decreased as continuously as possible. If a band engineered layer with a stepped bandgap is desired, the SiH₂Cl₂/NH₃ ratio is varied in discrete steps. A similar method can be applied for bandgap engineered silicon oxynitride layer deposition, where the SiH₂Cl₂/NH₃/N₂O ratio is varied instead.

An optional second dielectric film 6 can be deposited on and in contact with the band engineered layer 5. Deposition details for the second dielectric film are the same as for the first optional dielectric layer 4.

Blocking dielectric 7 can then be formed in contact with the band engineered layer 5 or the optional second dielectric layer 6. The blocking dielectric is preferably a high temperature oxide (HTO) (silicon dioxide) about 30 to about 200 angstroms thick, preferably about 50 angstroms thick, though other dielectrics, or oxides formed by other methods can be used.

A doped polysilicon layer can be then formed on and in contact with the blocking dielectric. It can be deposited and doped by any method, including in situ doping or ion implantation. P-type or n-type dopants can be used. The layer is then patterned together with the dielectric layers 3, 4, 5, 6, and/or 7 to form the gate electrode 9.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention.

All of the publications, patent applications and patents cited in this specification are incorporated herein by reference in their entirety.

1. A SONOS-type device, comprising:
(A) a semiconductor channel region located between a source region and a drain region;
(B) a tunneling dielectric in contact with the semiconductor channel region;
(C) a charge storage dielectric in contact with the tunneling dielectric;
(D) a blocking dielectric in contact with the charge storage dielectric; and
(E) a gate electrode in contact with the blocking dielectric;
wherein:
the charge storage dielectric comprises a band engineered layer that has a wider bandgap facing one of the blocking dielectric and the tunneling dielectric than facing the other one of the blocking dielectric and the tunneling dielectric; and
the semiconductor channel region comprises polysilicon.

2. The device of claim 1, wherein:
the SONOS-type device comprises a p-type SONOS-type device; and
the band engineered dielectric has a wider bandgap facing the tunneling dielectric than facing the blocking dielectric.

3. The device of claim 1, wherein:
the SONOS-type device comprises an n-type SONOS-type device; and
the band engineered dielectric has a wider bandgap facing the blocking dielectric than facing the tunneling dielectric.

4. The device of claim 1, wherein the band engineered layer comprises silicon nitride.

5. The device of claim 4, wherein:
the band engineered layer comprises silicon rich silicon nitride facing one of the tunneling dielectric and the blocking dielectric; and
the band engineered layer comprises nitrogen rich or stoichiometric silicon nitride facing the other one of the tunneling dielectric and the blocking dielectric.

6. The device of claim 1, wherein the band engineered layer comprises silicon oxynitride.

7. The device of claim 1, wherein the device comprises a TFT device and the semiconductor channel region comprises a polysilicon layer.

8. The device of claim 1, wherein the bandgap in the band engineered layer continuously varies in a direction from the tunneling dielectric to the blocking dielectric.

9. The device of claim 1, wherein the charge storage dielectric further comprises at least one of:
a first dielectric layer located between the tunneling dielectric and the band engineered layer, said first dielectric layer comprises a material different from that of the band engineered layer and different from that of the tunneling dielectric, and
a second dielectric layer located between the blocking dielectric and the band engineered layer, said second dielectric layer comprises a material different from that of the band engineered layer and different from that from a material of the blocking dielectric.

10. The device of claim 1, wherein the device comprises a portion of a monolithic three dimensional memory array.

11. A SONOS-type device, comprising:
(A) a semiconductor channel region located between a source region and a drain region;
(B) a tunneling dielectric in contact with the semiconductor channel region;
(C) a charge storage dielectric in contact with the tunneling dielectric;
(D) a blocking dielectric in contact with the charge storage dielectric; and
(E) a gate electrode in contact with the blocking dielectric;
wherein:
the charge storage dielectric comprises a band engineered layer that has a wider bandgap facing one of the blocking dielectric and the tunneling dielectric than facing the other one of the blocking dielectric and the tunneling dielectric; and
the device comprises a portion of a monolithic three dimensional memory array.

12. The device of claim 11, wherein the monolithic three-dimensional memory array comprises a first memory level located above a substrate and a second memory array monolithically level formed above the first memory level.

13. The device of claim 11, wherein the device comprises a TFT device and the semiconductor channel region comprises a polysilicon layer.

14. The device of claim 11, wherein the bandgap in the band engineered layer continuously varies in a direction from the tunneling dielectric to the blocking dielectric.

15. The device of claim 11, wherein:
the band engineered layer comprises silicon rich silicon nitride facing one of the blocking dielectric and the tunneling dielectric; and
the band engineered layer comprises nitrogen rich or stoichiometric silicon nitride facing the other one of the blocking dielectric and the tunneling dielectric.

16. The device of claim 11, wherein the charge storage dielectric further comprises at least one of:
a first dielectric layer located between the tunneling dielectric and the band engineered layer, said first dielectric layer comprises a material different from that of the band engineered layer and different from that of the tunneling dielectric, and
a second dielectric layer located between the blocking dielectric and the band engineered layer, said second dielectric layer comprises a material different from that of the band engineered layer and different from that of the blocking dielectric.

17. The device of claim 11, wherein:
the SONOS-type device comprises a p-type SONOS-type device; and
the band engineered dielectric has a wider bandgap facing the tunneling dielectric than facing the blocking dielectric.

18. The device of claim 11, wherein:
the SONOS-type device comprises an n-type SONOS-type device; and
the band engineered dielectric has a wider bandgap facing the blocking dielectric than facing the tunneling dielectric.

19. A SONOS-type device, comprising:
(A) a semiconductor channel region located between a source region and a drain region;
(B) a tunneling dielectric in contact with the semiconductor channel region;
(C) a charge storage dielectric in contact with the tunneling dielectric;
(D) a blocking dielectric in contact with the charge storage dielectric; and
(E) a gate electrode in contact with the blocking dielectric;
wherein the charge storage dielectric comprises:
(i) a band engineered layer that has a wider bandgap facing one of the blocking dielectric and the tunneling dielectric than facing the other one of the blocking dielectric and the tunneling dielectric; and
(ii) at least one of:
(a) a first dielectric layer located between the tunneling dielectric and the band engineered layer, said first dielectric layer comprises a material different from that of the band engineered layer and different from that of the tunneling dielectric, and
(b) a second dielectric layer located between the blocking dielectric and the band engineered layer, said second dielectric layer comprises a material different from that of the band engineered layer and different from that of the blocking dielectric.

20. The device of claim 19, wherein the device comprises a TFT device and the semiconductor channel region comprises a polysilicon layer.

21. The device of claim 19, wherein the bandgap in the band engineered layer continuously varies in a direction from the tunneling dielectric to the blocking dielectric.

22. The device if claim 19, wherein:
the band engineered layer comprises silicon rich silicon nitride facing one of the blocking dielectric and the tunneling dielectric; and
the band engineered layer comprises nitrogen rich or stoichiometric silicon nitride facing the other one of the blocking dielectric and the tunneling dielectric.

23. The device of claim 19, wherein the charge storage dielectric comprises the first dielectric layer and the second dielectric layer, which comprise either a same material or different materials from each other.

24. The device of claim 23, wherein the first and the second dielectric layers comprise silicon oxynitride, hafnium oxide, zirconium oxide, tantalum pentoxide, yttrium oxide, calcium oxide, or magnesium oxide.

25. The device of claim 19, wherein the band engineered layer comprises a silicon nitride layer that has a continuously variable composition, in which a silicon to nitrogen ratio continuously increases in a direction from one of the blocking dielectric and the tunneling dielectric to the other one of the blocking dielectric and the tunneling dielectric.

26. The device of claim 19, wherein the band engineered layer comprises a silicon nitride layer formed by varying a ratio of dichlorosilane to ammonia during CVD deposition using dichlorosilane and ammonia source gases.

27. The device of claim 19, wherein the device comprises a portion of a monolithic three dimensional memory array.

28. The device of claim 19, wherein:
the SONOS-type device comprises a p-type SONOS-type device; and
the band engineered dielectric has a wider bandgap facing the tunneling dielectric than facing the blocking dielectric.

29. The device of claim 19, wherein:
the SONOS-type device comprises an n-type SONOS-type device; and
the band engineered dielectric has a wider bandgap facing the blocking dielectric than facing the tunneling dielectric.
